(19) United States
(12) Patent Application Publication
(10) Pub. No.: US 2019/0078207 A1
(43) Pub. Date: Mar. 14, 2019

(54) GAS SUPPLY APPARATUS AND FILM FORMING APPARATUS

(71) Applicant: Tokyo Electron Limited, Tokyo (JP)

(72) Inventors: Hironori Yagi, Yamanashi (JP); Takashi Kakegawa, Yamanashi (JP); Katsumasa Yamaguchi, Yamanashi (JP); Yuichi Furuya, Yamanashi (JP); Kennan Mo, Yamanashi (JP)

(21) Appl. No.: 16/123,393

(22) Filed: Sep. 6, 2018

(30) Foreign Application Priority Data
Sep. 14, 2017 (JP) 2017-176441

(51) Int. Cl. C23C 16/455

(52) U.S. Cl. CPC C23C 16/45544; C23C 16/455

(57) ABSTRACT

A gas supply apparatus is capable of intermittently supplying a source gas into a processing container via a buffer tank and a first high speed opening/closing valve. The gas supply apparatus includes: an evacuation line connected to a second side of the buffer tank and configured to evacuate the inside of the buffer tank; and a second high speed opening/closing valve provided on the evacuation line.

### CROSS-REFERENCE TO RELATED APPLICATIONS

This application is based on and claims priority from Japanese Patent Application No. 2017-176441 filed on Sep. 14, 2017 with the Japan Patent Office, the disclosure of which is incorporated herein in its entirety by reference.

### TECHNICAL FIELD

The present disclosure relates to a gas supply apparatus and a film forming apparatus.

### BACKGROUND

When manufacturing a large scale integrated (LSI) circuit, a tungsten film is widely used for, for example, the gate electrode, contact with source·drain, and word line of memory of a metal oxide semiconductor field effect transistor (MOSFET).

The tungsten film is formed by an atomic layer deposition (ALD) method using, for example, tungsten hexachloride (WCl₆) gas and H₂ gas (see, e.g., Japanese Patent Laid-Open Publication No. 2016-145409). In an ALD method, in order to be able to supply required WCl₆ gas in a short time, WCl₆ gas generated by sublimating the WCl₆ contained in a film forming raw material tank is temporarily stored in a buffer tank, and then supplied to a processing container.

### SUMMARY

A gas supply apparatus according to an aspect of the present disclosure is configured to intermittently supplying a source gas into a processing container via a buffer tank and a first high speed opening/closing valve. The gas supply apparatus includes: an evacuation line connected to a second side of the buffer tank and configured to evacuate an inside of the buffer tank; and a second high speed opening/closing valve provided on the evacuation line.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic cross-sectional view of a film forming apparatus provided with a gas supply apparatus of a first embodiment.

FIG. 2 is a flowchart illustrating an example of a film forming method of a tungsten film.

FIG. 3 is a view illustrating a gas supply sequence in a film forming step.

FIG. 4 is a schematic cross-sectional view of a film forming apparatus provided with a gas supply apparatus of a second embodiment.

FIG. 5 is a flowchart illustrating an example of a film forming method of a tungsten film.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

In the above-described method, in a case where the pressure difference between the inside of the film forming raw material tank and the inside of the buffer tank is large at the start of a process, there is a problem that it takes time to stabilize a flow rate of WCl₆ gas when supplying the WCl₆ gas into the processing container.

Therefore, in an aspect of the present disclosure, an object is to provide a gas supply apparatus capable of stabilizing a flow rate of a source gas in a short time at the start of a process.

In order to achieve the above object, a gas supply apparatus according to an aspect of the present disclosure is configured to intermittently supply a source gas into a processing container via a buffer tank and a first high speed opening/closing valve. The gas supply apparatus includes: an evacuation line connected to a second side of the buffer tank and configured to evacuate the inside of the buffer tank; and a second high speed opening/closing valve provided on the evacuation line.

In the above-described gas supply apparatus, an orifice is provided on a second side of the second high speed opening/closing valve.

In the above-described gas supply apparatus, a pressure gauge that detects a pressure of the evacuation line and a pressure regulating valve whose opening degree is adjusted based on the pressure detected by the pressure gauge are provided on the second side of the second high speed opening/closing valve.

In the above-described gas supply apparatus, a buffer tank that temporarily stores the source gas supplied to the evacuation line is provided on the second side of the second high speed opening/closing valve.

In the above-described gas supply apparatus, a pressure regulating gas supply line that supplies a pressure regulating gas to the evacuation line is connected to the second side of the second high speed opening/closing valve.

In the above-described gas supply apparatus, the second high speed opening/closing valve is configured to be opened or closed at a speed equal to or substantially equal to that of the first high speed opening/closing valve.

A film forming apparatus according to an aspect of the present disclosure includes: a processing container; and a gas supply apparatus configured to intermittently supply a source gas into the processing container via a buffer tank and a first high speed opening/closing valve. The gas supply apparatus includes: an evacuation line connected to a second side of the buffer tank and configured to evacuate the inside of the buffer tank; and a second high speed opening/closing valve provided on the evacuation line.

According to the disclosed gas supply apparatus, it is possible to stabilize the flow rate of the source gas in a short time at the start of the process.

Hereinafter, an embodiment of the present disclosure will be described with reference to the drawings. Meanwhile, in the present specification and drawings, components having substantially the same configurations will be denoted by the same symbols, and the overlapping descriptions thereof will be omitted.

### First Embodiment

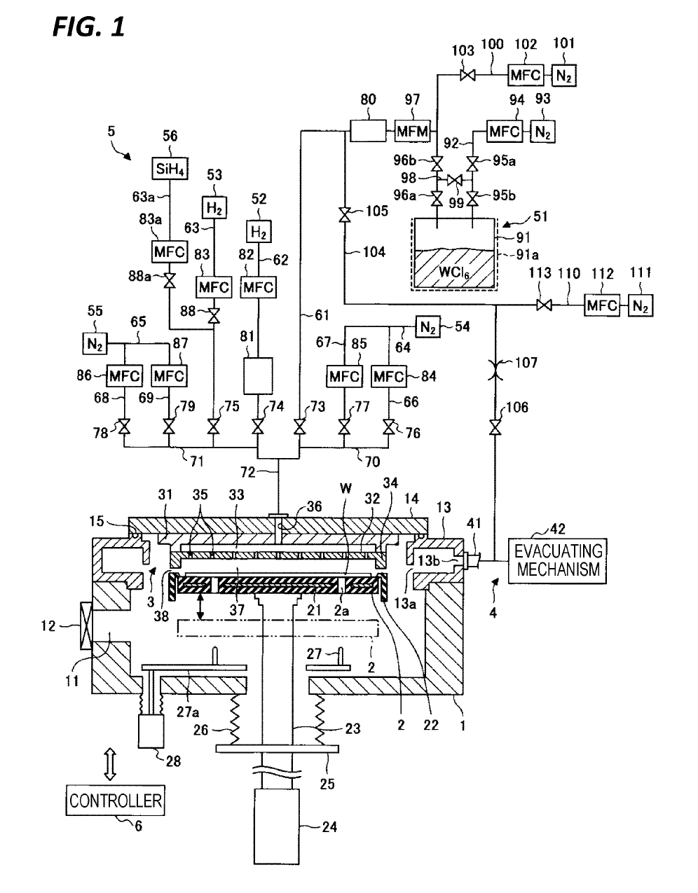

A film forming apparatus provided with a gas supply apparatus of a first embodiment will be described. FIG. 1 is a schematic cross-sectional view of the film forming apparatus provided with the gas supply apparatus of the first embodiment. The film forming apparatus of the first embodiment is configured as an apparatus capable of performing a film forming by an atomic layer deposition (ALD) method, and by a chemical vapor deposition (CVD) method.

The film forming apparatus includes a processing container 1, a susceptor 2 configured to horizontally support a semiconductor wafer (hereinafter, referred to as “wafer W”) which is a substrate in the processing container 1, a shower head 3 configured to supply a processing gas in a shower shape into the processing container 1, an evacuating unit configured to evacuate the inside of the processing container 1, a processing gas supply mechanism 5 configured to supply the processing gas to the shower head 3, and a controller 6.

The processing container 1 is made of a metal such as, for example, aluminum, and has a substantially cylindrical shape. A carry-in/out port 11 configured to carry-in or carry-out the wafer W is formed in a side wall of the processing container 1. The carry-in/out port 11 is configured to be opened or closed by a gate valve 12. An annular evacuation duct 13 which has a rectangular cross-sectional shape is provided on a body of the processing container 1. A slit 13a is formed along an inner peripheral surface in the evacuation duct 13. Further, an evacuation port 13b is formed in an outer wall of the evacuation duct 13. A ceiling wall 14 is provided on an upper surface of the evacuation duct 13 so as to close an upper opening of the processing container 1. A space between the ceiling wall 14 and the evacuation duct 13 is hermetically sealed with a seal ring 15.

The susceptor 2 has a disk shape having a size corresponding to the wafer W, and is supported by the support member 23. The susceptor 2 is made of a ceramic material such as, for example, aluminum nitride (AlN), or a metal material, for example, aluminum or a nickel-based alloy, and a heater 21 for heating the wafer W is embedded therein. The heater 21 is configured to generate heat by being supplied with power from a heater power source (not illustrated). The wafer W is controlled to be at a predetermined temperature by controlling the output of the heater 21 according to a temperature signal of a thermocouple (not illustrated) provided on the vicinity of a wafer placing surface on the upper surface of the susceptor 2.

The susceptor 2 is provided with a cover member 22 made of a ceramics such as, for example, alumina so as to cover an outer peripheral region of the wafer placing surface, and a side surface of the susceptor 2.

The support member 23 that supports the susceptor 2 penetrates a hole formed in a bottom wall of the processing container 1 from the center of the bottom surface of the susceptor 2 and extends downward of the processing container 1, and the lower end thereof is connected to an elevating mechanism 24. The susceptor 2 is configured to be movable up and down between a processing position illustrated in FIG. 1 and a transfer position where the wafer may be transferred as indicated by an alternate long and short dash line below the processing position via the support member 23 by the elevating mechanism 24. Further, a flange portion 25 is attached to the lower side of the processing container 1. A bellows 26 is provided between the bottom surface of the processing container 1 and the flange portion 25 to partition an atmosphere in the processing container 1 from an outer air and expand or contract according to an elevation operation of the susceptor 2.

Three wafer support pins 27 (only two are illustrated) are provided in the vicinity of the processing container 1 so as to protrude upward from an elevating plate 27a. The wafer support pins 27 are configured to be elevatable via the elevating plate 27a by a elevating mechanism 28 provided below the processing container 1, and configured to be inserted through through-holes 2a formed in the suscepter 2 in the transfer position so as to protrude and retreat from the upper surface of the susceptor 2. By elevating the wafer support pins 27 in this manner, the wafer W is delivered between a wafer transfer mechanism (not illustrated) and the susceptor 2.

The shower head 3 is made of a metal having a diameter substantially equal to that of the susceptor 2 and provided so as to face the susceptor 2. The shower head 3 includes a body portion 31 fixed to the ceiling wall 14 of the processing container 1 and a shower plate 32 connected below the body portion 31. A gas diffusion space 33 is formed between the body portion 31 and the shower plate 32. A gas introduction hole 36 is formed in the gas diffusion space 33 so as to penetrate the body portion 31 and the center of the ceiling portion 14 of the processing container 1. An annular protrusion 34 protruding downward is formed on the peripheral edge portion of the shower plate 32. Gas ejection holes 35 are formed on an inner flat surface of the annular protrusion 34 of the shower plate 32.

When the susceptor 2 is present at the processing position, a processing space 37 is formed between the shower plate 32 and the susceptor 2, and the annular protrusion 34 and the cover member 22 of the susceptor 2 come close to each other, thereby forming an annular gap 38.

An evacuating unit 4 includes an evacuation pipe 41 connected to the evacuation port 13b of the evacuation duct 13 and an evacuating mechanism 42 connected to the evacuation pipe 41 and including, for example, a vacuum pump or a pressure regulating valve. At the time of processing, the gas in the processing container 1 reaches the evacuation duct 13 via the slit 13a, and is evacuated from the evacuation duct 13 through the evacuation pipe 41 by the evacuating mechanism 42 of the evacuating unit 4.

The processing gas supply mechanism 5 includes a WCl₆ gas supply mechanism 51, a first H₂ gas supply source 52, a second H₂ gas supply source 53, a first N₂ gas supply source 54, a second N₂ gas supply source 55, and a SiH₄ gas supply source 56. The WCl₆ gas supply mechanism 51 supplies WCl₆ gas as a metal chloride gas which is a source gas. The first H₂ gas supply source 52 supplies H₂ gas as a reducing gas. The second H₂ gas supply source 53 supplies H₂ gas as an additional reducing gas. The first N₂ gas supply source 54 and the second N₂ gas supply source 55 supply N₂ gas which is a purge gas. The SiH₄ gas supply source 56 supplies SiH₄ gas.

The processing gas supply mechanism 5 includes a WCl₆ gas supply line 61, a first H₂ gas supply line 62, a second H₂ gas supply line 63, a first N₂ gas supply line 64, a second N₂ gas supply line 65, and a SiH₄ gas supply line 63a. The WCl₆ gas supply line 61 is a line extending from the WCl₆ gas supply mechanism 51. The first H₂ gas supply line 62 is a line extending from the first H₂ gas supply source 52. The second H₂ gas supply line 63 is a line extending from the second H₂ gas supply source 53. The first N₂ gas supply line 64 is a line extending from the first N₂ gas supply source 54, and supplying N₂ gas to the WCl₆ gas supply line 61 side. The second N₂ gas supply line 65 is a line extending from the second N₂ gas supply source 55, and supplying N₂ gas to the first H₂ gas supply line 62 side. The SiH₄ gas supply line 63a is a line extending from the SiH₄ gas supply source 56, and provided so as to be connected to the second H₂ gas supply line 63.

The first N₂ gas supply line 64 is branched off to a first continuous N₂ gas supply line 66 which always supplies N₂ gas during the film formation by the ALD method, and a first flash purge line 67 which supplies N₂ gas only during a purge step. Further, the second N₂ gas supply line 65 is branched off to a second continuous N₂ gas supply line 68 which always supplies N₂ gas during the film formation by the ALD method, and a second flash purge line 69 which supplies N₂ gas only during the purge step. The first continuous gas supply line 66 and the first flash purge line 67 are connected to a first connecting line 70, and the first connecting line 70 is connected to the WCl₆ gas supply line 61. Further, the second H₂ gas supply line 63, the second continuous N₂ gas supply line 58, and the second flash purge line 69 are connected to a second connecting line 71, and the second connecting line 71 is connected to the first H₂ gas supply line 62. The WCl₆ gas supply line 61 and the first H₂ gas supply line 62 are joined to a confluent pipe 72, and the confluent pipe 72 is connected to the above-described gas introduction hole 36.

On the most downstream side of the WCl₆ gas supply line 61, the first H₂ gas supply line 62, the second H₂ gas supply line 63, the first continuous N₂ gas supply line 66, the first flash purge line 67, the second continuous N₂ gas supply line 68, and the second flash purge line 69, opening/closing valves 73 to 79 are provided to switch gases at the time of ALD processing, respectively. The opening/closing valves 73 to 79 are ALD valves that may be opened and closed at a high speed. The ALD valves may be opened and closed at an interval of 0.5 second or less. Further, the ALD valves may be opened and closed at an interval of 0.01 second or less. Further, on the upstream side of the opening/closing valve of the first H₂ gas supply line 62, the second H₂ gas supply line 63, the first continuous N₂ gas supply line 66, the first flash purge line 67, the second continuous N₂ gas supply line 68, and the second flash purge line 69, mass flow controllers 82 to 87 as flow rate regulators are provided, respectively. The mass flow controller 83 is provided on an upstream side of a junction of the SiH₄ gas supply line 63a in the second H₂ gas supply line 63. The opening/closing valve 88 is provided between the mass flow controller 83 and the junction. Further, the SiH₄ gas supply line 63a is provided with a mass flow controller 83a and an opening/closing valve 88a in this order from the upstream side. Therefore, any one or both of H₂ gas and SiH₄ gas may be supplied via the second H₂ gas supply line 63. The WCl₆ gas supply line 61 and the first H₂ gas supply line 62 are provided with buffer tanks 80 and 81, respectively, so that required gas may be supplied in a short time.

The WCl₆ gas supply mechanism 51 includes a film forming raw material tank 91 which is a raw material container for containing the WCl₆. The WCl₆ is a solid raw material which is a solid at room temperature. A heater 91a is provided around the film forming raw material tank 91 and is configured to heat a film forming raw material in the film forming raw material tank 91 to an appropriate temperature so as to sublimate the WCl₆. In the film forming raw material tank 91, the above-described WCl₆ gas supply line 61 is inserted from the above.

Further, the WCl₆ gas supply mechanism 51 includes a carrier gas pipe 92 which is inserted into the film forming raw material tank 91 from the above, a carrier N₂ gas supply source 93 configured to supply N₂ gas which is a carrier gas to the carrier gas pipe 92, a mass flow controller 94 as a flow rate regulator which is connected to the carrier gas pipe 92, opening/closing valves 95a and 95b provided on a downstream of the mass flow controller 94, opening/closing valves 96a and 96b provided in the vicinity of the film forming raw material tank 91 of the WCl₆ gas supply line 61, and a flow meter 97. In the carrier gas pipe 92, the opening/closing valve 95a is provided at a position directly below the mass flow controller 94, and the opening/closing valve 95b is provided on the insertion end side of the carrier gas pipe 92. Further, the opening/closing valves 96a and 96b, and the flow meter 97 are arranged in an order of the opening/closing valve 96a, the opening/closing valve 96b, and the flow meter 97 from the insertion end of the WCl₆ gas supply line 61.

A bypass pipe 98 is provided so as to connect a position between the opening/closing valve 95a and the opening/closing valve 95b of the carrier gas pipe 92 and a position between the opening/closing valve 96a and the opening/closing valve 96b of the WCl₆ gas supply line 61. The bypass valve 98 is provided with an opening/closing valve 99. By closing the opening/closing valves 95b and 96a and opening the opening/closing valves 99, 95a, 96b, the N₂ gas supplied from the carrier N₂ gas supply source 93 is supplied to the WCl₆ gas supply line 61 via the carrier gas pipe 92 and the bypass pipe 98. As a result, the WCl₆ gas supply line 61 may be purged.

Further, an end portion of a downstream side of a diluted N₂ gas supply line 100 which supplies N₂ gas which is a diluent gas is joined to an upstream side of the flow meter 97 in the WCl₆ gas supply line 61. The end portion of a downstream side of the diluted N₂ gas supply line 100 is provided with a diluted N₂ gas supply source 101 which is a supply source of N₂ gas. The diluted N₂ gas supply line 100 is provided with a mass flow controller 102 and an opening/closing valve 103 in this order from the upstream side.

One end of an evacuation line 104 is connected to between the buffer tank 80 and the opening/closing valve 73 in the WCl₆ gas supply line 61, and the other end of the evacuation line 104 is connected to the evacuation pipe 41. Therefore, the inside of the buffer tank 80 may be evacuated through the evacuation line 104 by the evacuating mechanism 42.

The evacuation line 104 is provided with an opening/closing valve 105, an orifice 107, and an opening/closing valve 106 in this order from the upstream side.

The opening/closing valve 105 is an ALD valve that may be opened and closed at a high speed. The ALD valve may be opened and closed at an interval of 0.5 second or less. Further, the ALD valve may be opened and closed at an interval of 0.01 second or less. By the opening and closing operation of the opening/closing valve 105, the WCl₆ gas supplied from the film forming raw material tank 91 may be intermittently supplied to the evacuation line 104. The opening/closing valve 105 may be opened or closed at the same or substantially the same speed as the opening/closing valve 73. Therefore, WCl₆ gas may be supplied to and evacuated from the evacuation line 104 at the same cycle as the WCl₆ gas supplied to the processing space 37 from the film forming raw material tank 91 via the opening/closing valve 73.

The orifice 107 is provided between the opening/closing valve 105 and the opening/closing valve 105. The orifice 107 is provided so as to bring the pressure in the evacuation line 104 close to the pressure in the processing container 1 during the process.

The opening/closing valve 106 is provided on the downstream side of the orifice 107. By opening the opening/closing valve 106, the inside of the evacuation line 104 is evacuated by the evacuating mechanism 42.

An end portion of a downstream side of a pressure regulating gas supply line 100 which supplies a pressure regulating gas to the evacuation line 104 is joined to the downstream side of the opening/closing valve 105 in the evacuation line 104, and the upstream side of the orifice 107. The end portion of the upstream side of the pressure regulating gas supply line 110 is provided with a pressure regulating gas supply source 111 which is a supply source of a pressure regulating gas. The pressure regulating gas supply line 110 is provided with a mass flow controller 112 and an opening/closing valve 113 in this order from the upstream side. The pressure regulating gas which is supplied from the pressure regulating gas supply source 111 and whose flow rate is regulated by the mass flow controller 112 is supplied to the evacuation line 104 via the pressure regulating gas supply line 110. The pressure regulating gas may be, for example, N₂ gas.

The controller 6 includes a process controller having a microprocessor (computer) which controls respective components, specifically, for example, a valve, a power supply, a heater, and a pump, a user interface, and a storage unit. The respective components of the film forming apparatus are electrically connected and controlled by the process controller. The user interface is connected to the process controller, and is constituted by, for example, a keyboard for an operator to perform an input operation of commands to manage each component of the film forming apparatus, or a display which visualizes and displays the operating status of each component of the film forming apparatus. The storage unit is also connected to the process controller. The storage unit stores, for example, a control program for implementing various processings performed in the film forming apparatus under the control of the process controller, or a control program for implementing a predetermined processing for each component of the film forming apparatus according to the processing conditions, that is, for example, a processing recipe or various databases. The processing recipe is stored in a storage medium (not illustrated) in the storage unit. The storage medium may be a fixedly provided medium such as a hard disk or may be a portable medium such as a CDROM, a DVD, or a semiconductor memory. Further, the recipe may be properly transmitted from other devices through, for example, a dedicated line. As required, a predetermined processing recipe is loaded from the storage unit by, for example, an instruction from the user interface and executed by the process controller, and under the control of the process controller, the required processing in the film forming apparatus is performed.

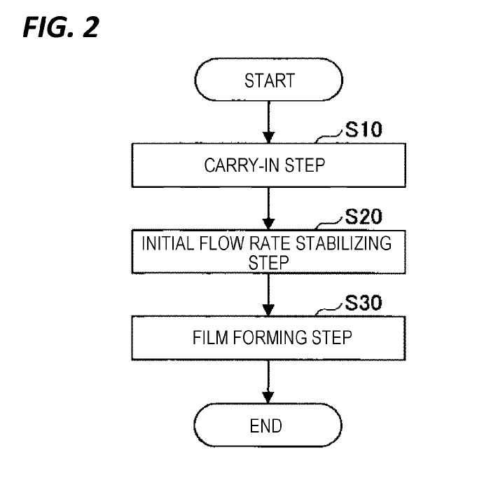

Next, a WCl₆ gas supply method will be described by taking a case where a tungsten film is formed by the ALD method using the film forming apparatus of the first embodiment illustrated in FIG. 1 as an example. In the gas supply method of the first embodiment, before forming a tungsten film on the wafer W by supplying WCl₆ gas into the processing container 1, WCl₆ gas is intermittently supplied to the evacuation line 104. Therefore, an initial flow rate of the WCl₆ supplied into the processing container 1 may be stabilized in a short time. Hereinafter, descriptions will be made with reference to FIG. 2. FIG. 2 is a flow chart illustrating an example of a film forming method of a tungsten film.

As illustrated in FIG. 2, the film forming method of the tungsten film includes a carry-in step S10, an initial flow rate stabilizing step S20, and a film forming step S30.

The carry-in step S10 is a step of carrying the wafer W into the processing container 1. In the carry-in step S10, the gate valve 12 is opened in a state where the susceptor 2 is lowered to the transfer position, and the wafer W is carried into the processing container 1 through the carry-in/out port 11 via a transfer device (not illustrated) and placed on the susceptor 2 heated to a predetermined temperature by the heater 21. Subsequently, the susceptor 2 is raised to the processing position and the inside of the processing container 1 is depressurized to a predetermined pressure. Thereafter, the opening/closing valves 76 and 78 are opened, and the opening/closing valves 73, 74, 75, 77, and 79 are closed. Therefore, N₂ gas is supplied from the first N₂ gas supply source 54 and the second N₂ gas supply source 55 to the processing container 1 via the first continuous N₂ gas supply line 66 and the second continuous N₂ gas supply line 68 so as to increase the pressure in the processing container 1, and stabilize the temperature of the wafer W on the susceptor 2. As for the wafer W, one having a base film on a surface of a silicon film having a recess such as a trench or a hole may be used. As for the base film, a titanium-based material film such as, for example, a TiN film, a TiSiN film, a Ti silicide film, a Ti film, a TiO film, and a TiAlN film may be considered. Further, as for the base film, a tungsten-based compound film such as, for example, a WN film, a WSix film, and a WSiN film may be considered. The tungsten film may be formed with good adhesion by forming the base film on the surface of the silicon film. Further, an incubation time may be shortened.

The initial flow rate stabilizing step S20 is a step of intermittently supplying WCl₆ gas to the evacuation line 104, and is executed after the carry-in step S10 is initiated. In the initial flow rate stabilizing step S20, first, WCl₆ gas is supplied to the WCl₆ gas supply line 61 so as to fill the buffer tank 80 with WCl₆ gas. Specifically, the opening/closing valves 95a, 95b, 96a, and 96b are opened in a state where the opening/closing valves 73 and 105 are closed, so that N₂ gas and WCl₆ gas are supplied from the carrier N₂ gas supply source 93 and the film forming raw material tank 91 to the WCl₆ gas supply line 61, respectively. Further, the opening/closing valve 103 is opened, so that N₂ gas is supplied from the diluted N₂ gas supply line 100 to the WCl₆ gas supply line 61. The WCl₆ gas and the N₂ gas supplied to the WCl₆ gas supply line 61 are filled in the buffer tank 80. The WCl₆ gas and the N₂ gas are intermittently supplied to the evacuation line 104 after the buffer tank 80 is filled with the WCl₆ gas and the N₂ gas. Specifically, the opening/closing valve 105 is opened and closed at high speed in a state where the opening/closing valve 73 is closed, so that the WCl₆ gas and the N₂ gas are intermittently supplied to the evacuation line 104. Further, the opening/closing valve 106 is opened, so that the WCl₆ gas and the N₂ gas supplied to the evacuation line 104 are evacuated by the evacuating mechanism 42 via the orifice 107. Therefore, prior to the film forming step S30, a gas supply environment substantially equivalent to that of the film forming step S30 may be implemented without supplying the WCl₆ gas and the N₂ gas into the processing container 1. Thus, the flow rate of WCl₆ gas may be stabilized in a short time at the start of the film forming step S30. The opening and closing timings of the opening/closing valve 105 may be the same or substantially the same as the opening and closing timings of the opening/closing valve 73 in the film forming step S30. Therefore, the gas supply environment in the film forming step S30 may be implemented with high accuracy.

In addition, in the initial flow rate stabilizing step S20, in order to bring the pressure in the evacuation line 104 close to the pressure in the processing space 37 during the film formation, the pressure regulating gas may be supplied from the pressure regulating gas supply source 111 to the evacuation line 104 by opening the opening/closing valve 113. At this time, the flow rate of the pressure regulating gas supplied to the evacuation line 104 may be regulated by the mass flow controller 112 so that the pressure in the evacuation line 104 becomes substantially the same as the pressure in the processing space 37 during the film formation.

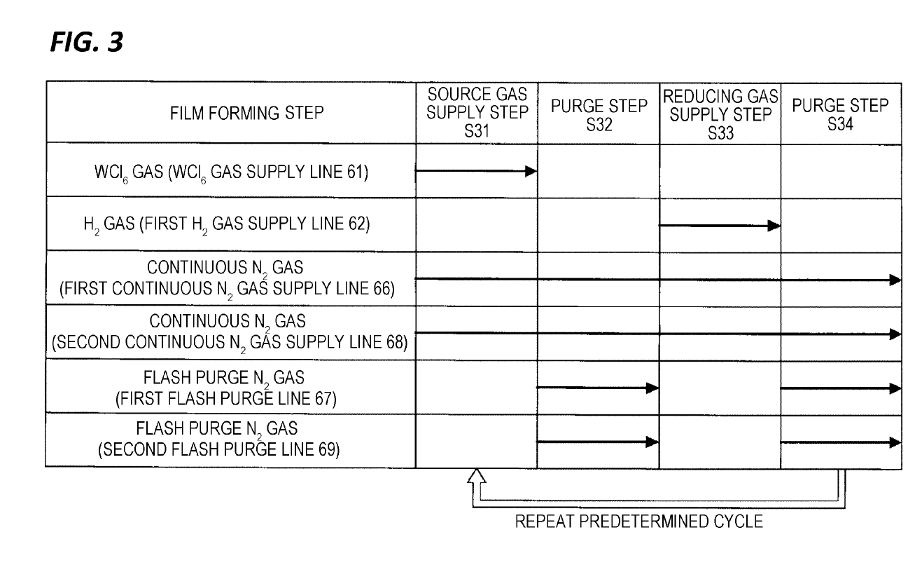

The film forming step S30 is a step of forming a tungsten film on the wafer W, and is executed after completing the initial flow rate stabilizing step S20. In the film forming step S30, a tungsten film is formed on the wafer W placed on the susceptor 2 in the processing container 1 by the ALD method. FIG. 3 is a view illustrating a gas supply sequence in the film forming step S30.

As illustrated in FIG. 3, in the film forming step S30, a series of operations including a source gas supply step S31, a purge step S32, a reducing gas supply step S33, and a purge step S34 is defined as one cycle, and a tungsten film having a desired film thickness is formed by controlling the number of cycles.

The source gas supply step S31 is a step of supplying WCl₆ gas which is a source gas to the processing space 37. In the source gas supply step S31, first, N₂ gas is continuously supplied from the first N₂ gas supply source 54 and the second N₂ gas supply source 55 via the first continuous N₂ gas supply line 66 and the second continuous N₂ gas supply line 68 in a state where the opening/closing valves 76 and 78 are opened. Further, the opening/closing valve 73 is opened, so that WCl₆ gas is supplied from the WCl₆ gas supply mechanism 51 to the processing space 37 via the WCl₆ gas supply line 61. At this time, WCl₆ gas, which is temporarily stored in the buffer tank 80 and stabilized by the initial flow rate stabilizing step S20, is supplied. Further, in the source gas supply step S31, H₂ gas serving as an additional reducing gas may be supplied into the processing container 1 via the second H₂ gas supply line 63 extending from the second H₂ gas supply source 53. When the reducing gas is supplied simultaneously with the WCl₆ gas in the source gas supply step S31, the supplied WCl₆ gas is activated. Thus, a film forming reaction in the subsequent reducing gas supply step S33 is likely to occur. Therefore, it is possible to maintain a high step coverage and to increase the film forming rate by increasing a deposited film thickness per one cycle. The flow rate of the additional reducing gas may be set to a flow rate at which the CVD reaction is not likely occur in the source gas supply step S31.

The purge step S32 is a step of purging excessive WCl₆ gas or the like in the processing space 37. In the purge step S32, the supply of WCl₆ gas is stopped by closing the opening/closing valve 73 while N₂ gas is continuously supplied through the first continuous N₂ gas supply line 66 and the second continuous N₂ gas supply line 68. Further, the opening/closing valves 77 and 79 are opened, so that N₂ gas (flash purge N₂ gas) is also supplied from the first flash purge line 67 and the second flash purge line 69, thereby purging the excessive WCl₆ gas in the processing space 37 with a large flow rate of N₂ gas.

The reducing gas supply step S33 is a step of supplying H₂ gas serving as a reducing gas to the processing space 37. In the reducing gas supply step S33, the supply of N₂ gas from the first flash purge lien 67 and the second flash purge line 69 is stopped by closing the opening/closing valves 77 and 79. Further, the opening/closing valve 74 is opened while N₂ gas is continuously supplied through the first continuous N₂ gas supply line 66 and the second continuous N₂ gas supply line 68. Therefore, H₂ gas as a reducing gas is supplied to the processing space 37 via the first H₂ gas supply line 62 from the first H₂ gas supply source 52. At this time, H₂ gas is temporarily stored in the buffer tank 81 and then supplied into the processing container 1. The WCl₆ gas absorbed on the wafer W is reduced by the reducing gas supply step S33. The flow rate of H₂ gas at this time may be set to an amount sufficient for the reduction reaction to occur.

The purge step S34 is a step of purging excessive H₂ gas in the processing space 37. In the purge step S34, the supply of H₂ gas from the first H₂ gas supply line 62 is stopped by closing the opening/closing valve 74 while N₂ gas is continuously supplied through the first continuous N₂ gas supply line 66 and the second continuous N₂ gas supply line 68. Further, by opening the opening/closing valves 77 and 79, N₂ gas (flash purge N₂ gas) is also supplied from the first flash purge line 67 and the second flash purge line 69, thereby purging the excessive H₂ gas in the processing space 37 with a large flow rate of N₂ gas.

A tungsten film having a desired film thickness may be formed by defining a series of operations including the source gas supply step S31, the purge step S32, the reducing gas supply step S33, and the purge step S34 described above as one cycle, and controlling the number of cycles.

As described above, the gas supply apparatus of the first embodiment is connected to the second side of the buffer tank 80, and includes the evacuation line 104 capable of evacuating the inside of the buffer tank 80 and the opening/closing valve 105 provided in the evacuation line 104. Therefore, before forming a tungsten film on the wafer W by supplying WCl₆ gas into the processing container 1, WCl₆ gas may be intermittently supplied to the evacuation line 104. As a result, the pressure in the buffer tank 80 and the pressure in the film forming raw material tank 91 may be set to be equivalent with the pressure during the film forming. Thus, the initial flow rate of the WCl₆ gas supplied into the processing container 1 at the start of film forming may be stabilized in a short time.

In the above example, descriptions have been made on the case where the initial flow rate stabilizing step S20 is initiated after the carry-in step S10 is initiated. However, the timing of initiating the initial flow rate stabilizing step S20 is not particularly limited as long as the timing is before the film forming step S30. For example, the initial flow rate stabilizing step S20 may be initiated simultaneously with the initiation of the carry-in step S10. When the initial flow rate stabilizing step S20 is initiated simultaneously with the initiation of the carry-in step S10, the carry-in step S10 and the initial flow rate stabilizing step S20 may proceed simultaneously. Thus, the time until the film forming step S30 is initiated may be shortened, and the productivity is improved.

### Second Embodiment

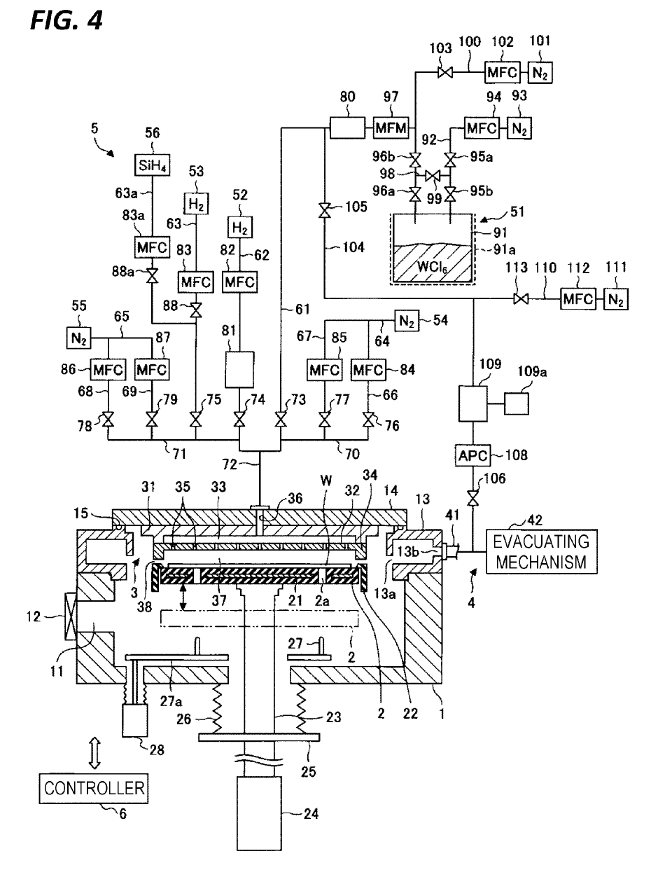

A film forming apparatus provided with a gas supply apparatus of a second embodiment will be described. FIG. 4 is a schematic cross-sectional view of a film forming apparatus provided with a gas supply apparatus of the second embodiment. The film forming apparatus of the second embodiment includes a buffer tank 109, a pressure gauge 109a, and an auto pressure control (APC) valve 108 at the second side of the opening/closing valve 105 instead of the orifice 107 illustrated in FIG. 1. Since the other configuration may be the same as that of the first embodiment, descriptions on the same configuration as that of the first embodiment will be omitted below.

The evacuation line 104 is provided with the opening/closing valve 105, the buffer tank 109, the APC valve 108, and the opening/closing valve 106 in this order from the upstream side.

The opening/closing valve 105 is an ALD valve capable of opening and closing at high speed. The ALD valve may be opened and closed at an interval of 0.5 second or less. Further, the ALD valve may be opened and closed at an interval of 0.01 second or less. By the opening and closing operation of the opening/closing valve 105, the WCl₆ gas supplied from the film forming raw material tank 91 may be intermittently supplied to the evacuation line 104. The opening/closing valve 105 may be opened or closed at the same or substantially the same speed as the opening/closing valve 73. Therefore, WCl₆ gas may be supplied to the evacuation line 104 at the same cycle as the WCl₆ gas supplied to the processing space 37 from the film forming raw material tank 91 via the opening/closing valve 73.

The buffer tank 109 stores the WCl₆ gas and N₂ gas supplied to the evacuation line 104. Since the buffer tank 109 is provided, the volume of the evacuation line 104 may be brought close to the volume of the processing space 37. The buffer tank 109 is provided with the pressure gauge 109a that detects the pressure in the buffer tank 109. The pressure gauge 109a may be, for example, a capacitance monometer.

The APC valve 108 is a valve that automatically regulates the opening degree based on the pressure detected by the pressure gauge 109a. For example, when the pressure detected by the pressure gauge 109a is lower than a predetermined pressure which is set in advance, the APC valve 109 regulates the opening degree to be decreased. Meanwhile, when the pressure detected by the pressure gauge 109a is higher than a predetermined pressure which is set in advance, the APC valve 109 regulates the opening degree to be increased. The predetermined pressure may be, for example, the pressure in the processing space 37 during the film formation.

The opening/closing valve 106 is provided on the downstream side of the APC valve 108. When the opening/closing valve 106 is opened, the inside of the evacuation line 104 is evacuated by the evacuating mechanism 42.

An end portion of a downstream side of a pressure regulating gas supply line 110 which supplies a pressure regulating gas to the evacuation line 104 is joined to the downstream side of the opening/closing valve 105 in the evacuation line 104, and the upstream side of the buffer tank 109. The end portion of the upstream side of the pressure regulating gas supply line 110 is provided with the pressure regulating gas supply source 111 which is the supply source of the pressure regulating gas. The pressure regulating gas supply line 110 is provided with the mass flow controller 112 and the opening/closing valve 113 in this order from the upstream side. The pressure regulating gas which is supplied from the pressure regulating gas supply source 111 and whose flow rate is regulated by the mass flow controller 112 is supplied to the evacuation line 104 via the pressure regulating gas supply line 110. The pressure regulating gas may be, for example, N₂ gas.

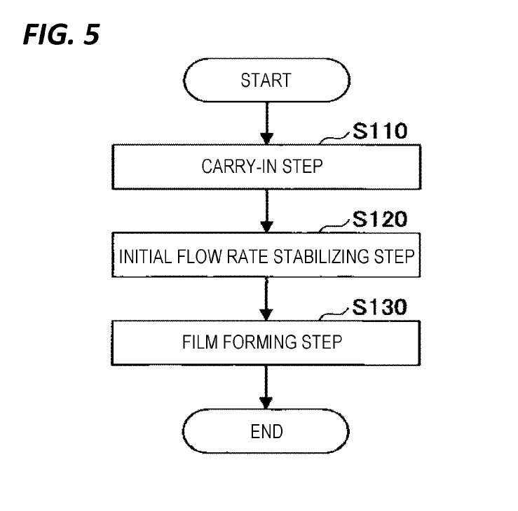

Next, a WCl₆ gas supply method will be described with respect to a case where a tungsten film is formed by the ALD method using the film forming apparatus of the second embodiment illustrated in FIG. 4 as an example. In the gas supply method of the second embodiment, before forming a tungsten film on the wafer W by supplying WCl₆ gas into the processing container 1, WCl₆ gas is intermittently supplied to the evacuation line 104. Therefore, an initial flow rate of the WCl₆ supplied into the processing container 1 may be stabilized in a short time. Hereinafter, descriptions will be made with reference to FIG. 5. FIG. 5 is a flow chart illustrating an example of a film forming method of a tungsten film.

As illustrated in FIG. 5, the film forming method of the tungsten film includes a carry-in step S110, an initial flow rate stabilizing step S120, and a film forming step S130.

The carry-in step S110 is a step of carrying the wafer W into the processing container 1. The carry-in step S110 may be the same as the carry-in step S10 in the film forming method of the tungsten film of the first embodiment.

The initial flow rate stabilizing step S120 is a step of intermittently supplying WCl₆ gas to the evacuation line 104, and is executed after the carry-in step S10 is initiated. In the initial flow rate stabilizing step S120, first, WCl₆ gas is supplied to the WCl₆ gas supply line 61 so as to fill the buffer tank 80 with WCl₆ gas. Specifically, the opening/closing valves 95a, 95b, 96a, and 96b are opened in a state where the opening/closing valves 73 and 105 are closed, so that N₂ gas and WCl₆ gas are supplied from the carrier N₂ gas supply source 93 and the film forming raw material tank 91 to the WCl₆ gas supply line 61, respectively. Further, the opening/closing valve 103 is opened, so that N₂ gas is supplied from the diluted N₂ gas supply line 100 to the WCl₆ gas supply line 61. The WCl₆ gas and the N₂ gas supplied to the WCl₆ gas supply line 61 are filled in the buffer tank 80. The WCl₆ gas and the N₂ gas are intermittently supplied to the evacuation line 104 after the buffer tank 80 is filled with the WCl₆ gas and the N₂ gas. Specifically, the opening/closing valve 105 is opened at a high speed in a state where the opening/closing valve 73 is closed, so that the WCl₆ gas and the N₂ gas are intermittently supplied to the evacuation line 104. Further, the opening/closing valve 106 is opened, so that the WCl₆ gas and the N₂ gas supplied to the evacuation line 104 are evacuated by the evacuating mechanism 42 via the buffer tank 109 and the APC valve 108. At this time, the opening degree of the APC valve 108 is automatically regulated based on the pressure detected by the pressure gauge 109a. Specifically, the opening degree of the APC valve 108 is controlled such that the pressure detected by the pressure gauge 109a becomes a predetermined pressure that is set in advance, for example, the pressure in the processing space 37 during the film formation. Therefore, prior to the film forming step S130, a gas supply environment substantially equivalent to that of the film forming step S130 may be implemented without supplying the WCl₆ gas and the N₂ gas into the processing container 1. Thus, the flow rate of WCl₆ gas may be stabilized in a short time at the start of the film forming step S130. The opening and closing timings of the opening/closing valve 105 may be the same or substantially the same as the opening and closing timings of the opening/closing valve 73 in the film forming step S130. Therefore, the gas supply environment in the film forming step S130 may be implemented with high accuracy.

In addition, in the initial flow rate stabilizing step S120, in order to bring the pressure in the evacuation line 104 close to the pressure in the processing space 37 during the film formation, the pressure regulating gas may be supplied from the pressure regulating gas supply source 111 to the evacuation line 104 by opening the opening/closing valve 113. At this time, the flow rate of the pressure regulating gas supplied to the evacuation line 104 may be regulated by the mass flow controller 112 so that the pressure in the evacuation line 104 or the pressure in the buffer tank 109 becomes substantially the same as the pressure in the processing space 37 during the film formation.

The film forming step S130 is a step in which a tungsten film is formed on the wafer W, and is executed after the initial flow rate stabilizing step S120 is completed. The film forming step S130 may be the same as the film forming step S30 in the film forming method of the tungsten film of the first embodiment.

As described above, the gas supply apparatus of the second embodiment is connected to the second side of the buffer tank 80, and includes the evacuation line 104 capable of evacuating the inside of the buffer tank 80 and the opening/closing valve 105 provided in the evacuation line 104. Therefore, before a tungsten film is formed on the wafer W by supplying WCl₆ gas into the processing container 1, WCl₆ gas may be intermittently supplied to the evacuation line 104. As a result, the pressure in the buffer tank 80 and the pressure in the film forming raw material tank 91 may be set to be equivalent with the pressure during the film forming. Thus, the initial flow rate of the WCl₆ gas supplied into the processing container 1 at the start of film forming may be stabilized in a short time.

In particular, in the second embodiment, the pressure in the buffer tank 109 provided in the evacuation line 104 is regulated by the APC valve 108 to be brought to the pressure in the processing space 37 during the film formation. Therefore, prior to the film forming step S130, the gas supply environment of the processing space 37 in the film forming step S130 may be implemented with high accuracy. As a result, the flow rate of WCl₆ gas at the start of the film forming step S130 may be stabilized in a shorter time than in the first embodiment.

In the above example, descriptions have been made on the case where the initial flow rate stabilizing step S120 is initiated after the carry-in step S110 is initiated, but the timing of initiating the initial flow rate stabilizing step S120 is not particularly limited as long as the timing is before the film forming step S130. For example, the initial flow rate stabilizing step S120 may be initiated simultaneously with the initiation of the carry-in step S110. When the initial flow rate stabilizing step S120 is initiated simultaneously with the initiation of the carry-in step S110, the carry-in step S110 and the initial flow rate stabilizing step S120 may proceed simultaneously. Thus, the time until the film forming step S130 is initiated may be shortened, and the productivity is improved.

In each of the above embodiments, the opening/closing valve 73 and the opening/closing valve 105 are examples of a first high speed opening/closing valve and a second high speed opening/closing valve, respectively.

In the above embodiments, descriptions have been made on the case where a tungsten film is formed by using WCl₆ gas as a metal chloride gas as an example, but the present disclosure may be applied to a case where a metal film is formed by alternately supplying a metal chloride gas and a reducing gas. Examples of the metal chloride gas include other tungsten chloride gases, for example, WClL₅ gas, which exhibits substantially the same behavior as that of the WCl₆ gas. The WCl₅ which is solid at room temperature may be used as a film forming raw material. Further, the present disclosure may be applied to a case where a molybdenum film is formed by using, for example, a molybdenum chloride gas and a reducing gas or a case where a tantalum film is formed using a tantalum chloride gas and a reducing gas. In these cases, molybdenum chlorides or tantalum chlorides which are solid at room temperature may be used as a film forming raw material. Further, in the above embodiments, a gas obtained by sublimating a solid raw material is used as a source gas. However, a gas obtained by vaporizing a liquid raw material may also be used as a source gas.

Further, in the above embodiments, descriptions have been made on the case where H₂ gas is used as a reducing gas as an example, but any reducing gas containing hydrogen may be used. Besides H₂ gas, for example, SiH₄ gas, B₂H₆ gas, and NH₃ gas may be used. Two or more of H₂ gas, SiH₄ gas, B₂H₆ gas, and NH₃ gas may be supplied. Further, besides these gases, other reducing gases, for example, PH₃ gas or SiH₂Cl₂ gas may be used. H₂ gas may be used from the view point of obtaining a low resistance value by further reducing impurities in the film. Further, other inert gases (e.g., Ar gas) may be used as purge gas and carrier gas instead of N₂ gas.

Further, in the above embodiments, a semiconductor wafer has been described as an example of a substrate. However, the semiconductor wafer may be a silicon wafer, or a compound semiconductor wafer such as GaAs, SiC, and GaN. In addition, the substrate is not limited to a semiconductor wafer. The present disclosure may be applied to, for example, a glass substrate or a ceramic substrate used in a flat panel display (FPD), such as a liquid display device.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A gas supply apparatus comprising:
an evacuation line connected to a second side of a buffer tank and configured to evacuate an inside of the buffer tank; and
a second high speed opening/closing valve provided on the evacuation line,
wherein the gas supply apparatus is configured to intermittently supply a source gas into a processing container via the buffer tank and a first high speed opening/closing valve.

2. The gas supply apparatus of claim 1, wherein an orifice is provided on a second side of the second high speed opening/closing valve.

3. The gas supply apparatus of claim 1, wherein a pressure gauge that detects a pressure of the evacuation line and a pressure regulating valve whose opening degree is adjusted based on the pressure detected by the pressure gauge are provided on the second side of the second high speed opening/closing valve.

4. The gas supply apparatus of claim 3, wherein a buffer tank that temporarily stores the source gas supplied to the evacuation line is provided on the second side of the second high speed opening/closing valve.

5. The gas supply apparatus of claim 1, wherein a pressure regulating gas supply line that supplies a pressure regulating gas to the evacuation line is connected to the second side of the second high speed opening/closing valve.

6. The gas supply apparatus of claim 1, wherein the second high speed opening/closing valve is configured to be opened or closed at a speed equal to or substantially equal to that of the first high speed opening/closing valve.

7. A film forming apparatus comprising:
a processing container; and
a gas supply apparatus configured to intermittently supply a source gas into the processing container via a buffer tank and a first high speed opening/closing valve,
wherein the gas supply apparatus includes:
an evacuation line connected to a second side of the buffer tank and configured to evacuate the inside of the buffer tank; and
a second high speed opening/closing valve provided on the evacuation line.
